(19) United States
(12) Patent Application Publication
(10) Pub. No.: US 2013/0038378 A1
(43) Pub. Date: Feb. 14, 2013

(54) Touch Sensing With A Common Driver

(71) Applicants: Tajeshwar Singh, Klaebu (NO); Trond Jarle Pedersen, Trondheim (NO)

(72) Inventors: Tajeshwar Singh, Klaebu (NO); Trond Jarle Pedersen, Trondheim (NO)

(21) Appl. No.: 13/209,042

(22) Filed: Aug. 12, 2011

(51) Int. Cl. H03K 17/96

(52) U.S. Cl. 327/517

(57) ABSTRACT

In one embodiment, an apparatus includes a touch sensor including drive electrodes. The apparatus also includes sense electrodes arranged along a first axis and a second axis. The first and second axes are substantially perpendicular to each other. The apparatus also includes one or more computer-readable non-transitory storage media coupled to the touch sensor that embody logic that drives all the drive electrodes substantially simultaneously with a common drive signal.

### BACKGROUND

A touch sensor may detect the presence and location of a touch or the proximity of an object (such as a user's finger or a stylus) within a display area of the touch sensor overlaid on a display screen. In a touch-sensitive display application, the touch sensor enables a user to interact directly with what is displayed on the screen, rather than indirectly with a mouse or touchpad. A touch sensor may be attached to or provided as part of a desktop computer, laptop computer, tablet computer, personal digital assistant (PDA), smartphone, satellite navigation device, telephone, portable media player, portable game console, kiosk computer, point-of-sale device, or other suitable device. A control panel on a household or other appliance may include a touch sensor.

There are a number of different types of touch sensors, such as (for example) resistive touch screens, surface acoustic wave touch screens, and capacitive touch screens. Herein, reference to a touch sensor may encompass a touch screen, and vice versa, where appropriate. A capacitive touch screen may include an insulator coated with a substantially transparent conductor in a particular pattern. When an object touches or comes within close proximity of the surface of the touch screen, a change in capacitance may occur within the touch screen at the location of the touch or proximity. A controller may process the change in capacitance to determine its position on the touch screen.

A conventional capacitive touch screen may include multiple pulse drivers arranged along one axis and multiple sensing circuits arranged along another axis. The pulse drivers may be pulsed sequentially and the signal may be measured on all the sensing circuits substantially simultaneously to determine whether and where a touch or proximity input has occurred on the touch screen. In this manner, each line of the screen may be sensed sequentially and the movement of the pulsing from one pulse driver to the next across the whole touch screen may provide a single scan of the touch screen.

### BRIEF DESCRIPTION OF THE DRAWINGS

FIG. 1 illustrates a conventional capacitive touch screen.

FIG. 2 illustrates an example capacitive touch screen with a common drive signal.

FIGS. 3 illustrates an example dual-layer sensor design for an example touch screen.

FIGS. 4A-4C illustrate an example single-layer sensor design with dual-layer bridges for an example touch screen.

FIGS. 5A-5C illustrate an example single-layer sensor design with single-layer bridges for an example touch screen.

FIG. 6 illustrates an example touch-screen system.

### DESCRIPTION OF EXAMPLE EMBODIMENTS

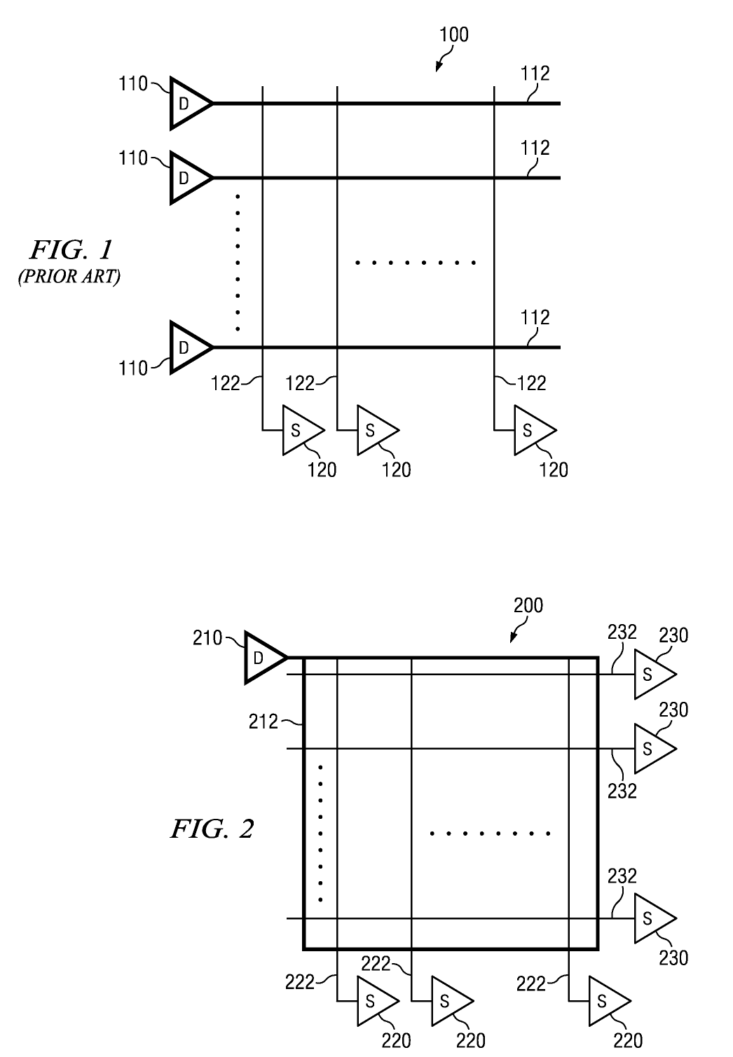

FIG. 1 illustrates a conventional capacitive touch screen 100. Touch screen 100 includes an array of drivers 110 coupled to drive lines 112 and sensors 120 coupled to sense lines 122. One or more drive electrodes may form each drive line 112, and one or more sense electrodes may form each sense line 122. Herein, reference to a drive line may encompass one or more drive electrodes, and vice versa, where appropriate. Similarly, reference to a sense line may encompass one or more sense electrodes, and vice versa, where appropriate. Touch screen 100 may implement a mutual-capacitance form of touch sensing. In such an implementation, a drive line 112 and a sense line 122 (or drive and sense electrodes making up drive line 112 and sense line 122) capacitively coupled to each other may form a capacitive node and a change in capacitance at the capacitive node may indicate a touch or the proximity of an object at the position of the capacitive node in touch screen 100. In a single-layer configuration, drive and sense lines 112 and 122 may be disposed in a pattern on one side of a substrate. In such a configuration, a pair of drive and sense lines 112 and 122 capacitively coupled to each other across a gap between them may form a capacitive node. In a two-layer configuration, drive lines 112 may be disposed in a pattern on one side of a substrate and sense lines 122 may be disposed in a pattern on another side of the substrate. In such a configuration, an intersection of a drive line 112 and a sense line 122 may form a capacitive node. Such an intersection may be a location where drive line 112 and sense line 122 “cross” or come nearest each other in their respective planes. Drive and sense lines 112 and 122 do not make electrical contact with each other—instead they are capacitively coupled to each other across the substrate at the intersection. In the example of FIG. 1, drive lines 112 are arranged along a first axis and sense lines 122 are arranged along a second axis that is substantially perpendicular to the first axis. Drivers 110 may provide one or more signal patterns across drive lines 112 that are detected by sensors 120 via sense lines 122. The location of a touch on screen 100 may be detected by detecting disturbances (using sensors 120 and sense lines 122) in the signal pattern(s) provided by drivers 110 caused by the touch on screen 100.

Drive lines 112 may be pulsed sequentially, and each pulse may be measured on all sensors 120 (via sense lines 122) substantially simultaneously to determine whether and where a touch or proximity input has occurred on touch screen 100. In this manner, each line of touch screen 100 along the axis of drive lines 112 may be sensed sequentially and the movement of the pulsing from one driver 110 to the next across touch screen 100 may provide a single scan of touch screen 100. The coordinates of a touch on or an object's proximity to touch screen 100 may be determined based on which of sensors 120 detected a change in capacitance using the pulse provided by corresponding drive electrode(s) 110 and when the detected change in capacitance occurred, because drivers 110 are activated sequentially. Such operations of touch screen 100 may require sensors 120 to operate at a rapid rate to maintain an acceptable screen refresh rate. Sequentially pulsing drivers 110 may cause longer screen scan time periods.

FIG. 2 illustrates an example capacitive touch screen 200 with a common drive signal. Touch screen 200 includes one or more drivers 210 that provide a common drive signal across drive lines 212. Touch screen 200 also includes an array of sensors 220 coupled to sense lines 222 and an array of sensors 230 coupled to sense lines 232. One or more drive electrodes may form each drive line 212, and one or more sense electrodes may form each sense line 222 or 232. Drive lines 212 and sense lines 222 and 232 (or drive and sense electrodes making up drive lines 212 and sense lines 222 and 232) may form capacitive nodes. For example, a drive line 212 and a sense line 222 or 232) may be capacitively coupled to each other across a gap between them and form a capacitive node. As another example, drive lines 212 may be located in a different plane from sense lines 222 and 232. An intersection of a drive line 212 and a sense line 222 or 232 may form a capacitive node. Such an intersection may be a location where drive line 212 and sense line 222 “cross” or come nearest each other in their respective planes. Drive and sense lines 212 and 222 do not make electrical contact with each other—instead they are capacitively coupled to each other across a substrate at the intersection. A change in capacitance at a capacitive node in touch screen 200 may indicate a touch or the proximity of an object at the position of the capacitive node in touch screen 200. Although this disclosure describes particular configurations of particular electrodes and lines forming particular nodes, this disclosure contemplates any suitable configuration of any suitable electrodes and lines forming any suitable nodes. Moreover, this disclosure contemplates any suitable electrodes disposed on any suitable number of any suitable substrates in any suitable patterns.

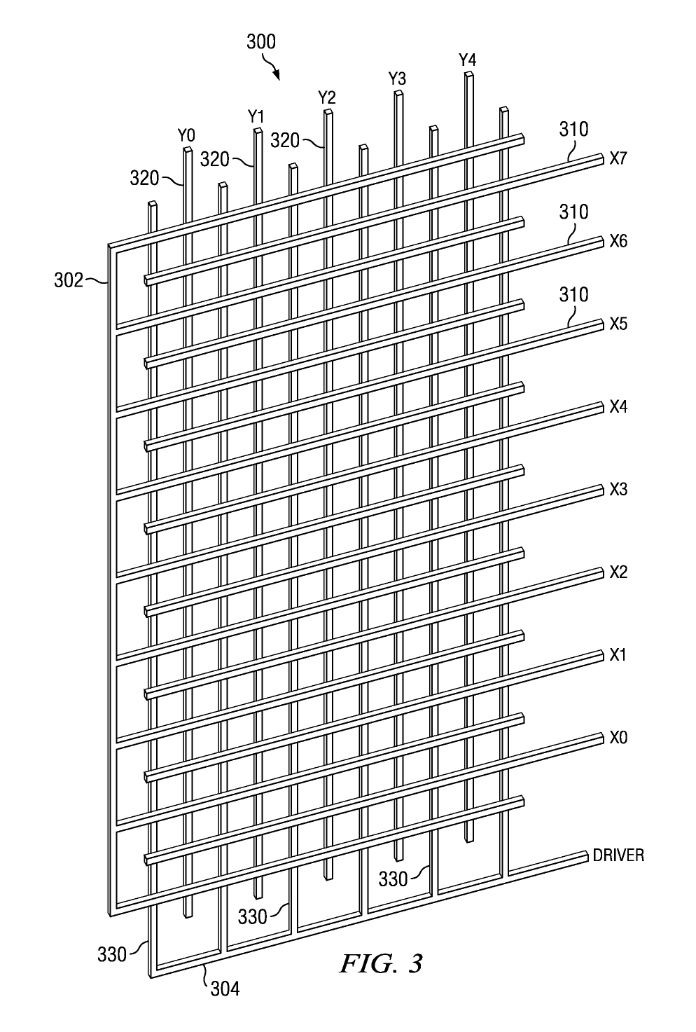

In the example of FIG. 2, sense lines 222 are arranged along a first axis and sense lines 232 are arranged along a second axis that is substantially perpendicular to the first axis. Driver(s) 210 (e.g., one or more signal generators) may provide a common signal pattern across drive lines 212 that are detected by sensors 220 and 230 via sense lines 222 and 232, respectively. Sensors 220 and 230 may be configured to sense charge and provide measurement signals representing capacitances. The location of a touch on screen 100 may be detected by detecting disturbances (using sensors 220 and 230) in the common signal pattern provided by driver 210 caused by the touch on screen 200. Example layouts of screen 200 are discussed below regarding FIGS. 3-6.

Drive lines 212 may all be pulsed at the same time and the pulse may be measured on all sensors 220 and 230 substantially simultaneously to determine whether and where a touch or proximity input has occurred on touch screen 200. In this manner, all lines 222 and 232 of touch screen 200 may be sensed at or near the same time. The coordinates of a touch on screen 200 or of an object's proximity to touch screen 200 may be determined based on which of sensors 220 and 230 experienced an interpolation of the common pulse provided by driver(s) 210. In particular embodiments, the configuration and/or operation of touch screen 200 may provide one or more advantages. For example, sensors 220 and 230 may operate at a lower rate than sensors 120 of FIG. 1 while maintaining an acceptable screen refresh rate because drive lines 212 are pulsed at the same time and not sequentially. As another example, screen scan time periods of touch screen 200 may be lower than touch screen 100 of FIG. 1 because drive lines 212 are pulsed at the same time and not sequentially.

In particular embodiments, touch screen 200 may comprise a transparent cover panel provided covering the sense electrodes. In one example, the transparent panel may be made of a resilient, transparent material suitable for repeated touching. Examples of the transparent material include glass, polycarbonate or PMMA (poly(methyl methacrylate)). In one example, drive lines 212, sense lines 222, and sense lines 232 may be made of PEDOT (poly(3,4-ethylenedioxythiophene)) or ITO (indium tin oxide). In other examples, drive lines 212, sense lines 222, and sense lines 232 may be made of conductive mesh, which may be of copper, silver or other conductive materials.

Although this disclosure describes and illustrates lines 212, 222, and 232 as straight, continuous lines running perpendicular to each other, this disclosure contemplates lines 212, 222, and 232 having any suitable configuration including any suitable shapes with any suitable macro-features and any suitable micro-features. As an example and not by way of limitation, lines 212, 222, and 232 may include electrodes having disc, square, or rectangle shapes forming a diamond, snowflake, triangle, or bar pattern or a suitable combination of such patterns. In addition, lines 212, 222, and 232 may be interdigitated with each other. The shapes of the electrodes may have a solid fill (made of ITO for example) or a mesh fill (made of, for example, fine lines of metal or other conductive material occupying approximately 5% (or less) of the area of the shapes). Although this disclosure describes particular fills for particular shapes for particular electrodes, this disclosure contemplates any suitable fill for any suitable shape for any suitable electrode.

FIG. 3 illustrates an example dual-layer sensor design for example touch screen 300. Touch screen 300 includes layers 302 and 304. Layer 302 includes sense lines 310 and drive lines 312 arranged such that a drive line 312 is adjacent to every sense line 310. Layer 304 includes sense lines 320 and drive lines 322 arranged such that a drive line 322 is adjacent to every sense line 320. Sense lines 310 are arranged along a first axis and sense lines 320 are arranged along a second axis that is substantially perpendicular to the first axis. Both drive lines 312 and 322 carry a common drive signal for all of touch screen 300. One or more drive electrodes may form each drive line 312 and 322, and one or more sense electrodes may form each sense line 310 and 320. Drive lines 312 and sense lines 310 form capacitive nodes. Drive lines 322 and sense lines 320 form capacitive nodes. For example, a drive line 312 and an adjacent sense line 310 may be capacitively coupled to each other across a gap between them and form a capacitive node. As another example, drive line 322 and an adjacent sense line 320 may be capacitively coupled to each other across a gap between them and form a capacitive node. Drive lines 312 and 322 are not in electrical contact with sense lines 310 and 320—instead they are capacitively coupled to each other. A change in capacitance at a capacitive node in touch screen 300 may indicate a touch or the proximity of an object at the position of the capacitive node in touch screen 300.

In particular embodiments, layers 302 and 304 include glass, polycarbonate or PMMA (poly(methyl methacrylate)). Lines 310, 312, 320, and 322 may be made of PEDOT (poly(3,4-ethylenedioxythiophene)), ITO (indium tin oxide), or conductive mesh. Conductive mesh may include copper, silver or other conductive materials.

In particular embodiments, drive lines 312 and 322 may all be pulsed at substantially the same time and the pulse may be measured using sense lines 310 and 320 substantially simultaneously to determine whether and where a touch or proximity input has occurred on touch screen 300. In this manner, all lines 310 and 320 of touch screen 300 may be sensed at or near the same time. The coordinates of a touch on screen 300 or of an object's proximity to screen 300 may be determined based on which of sense lines 310 and 320 experienced a disturbance to the common pulse on driver lines 312 and 322. In particular embodiments, screen 300 may have the same benefits discussed above with respect to FIG. 2 because it uses a common drive signal for the entire screen 300.

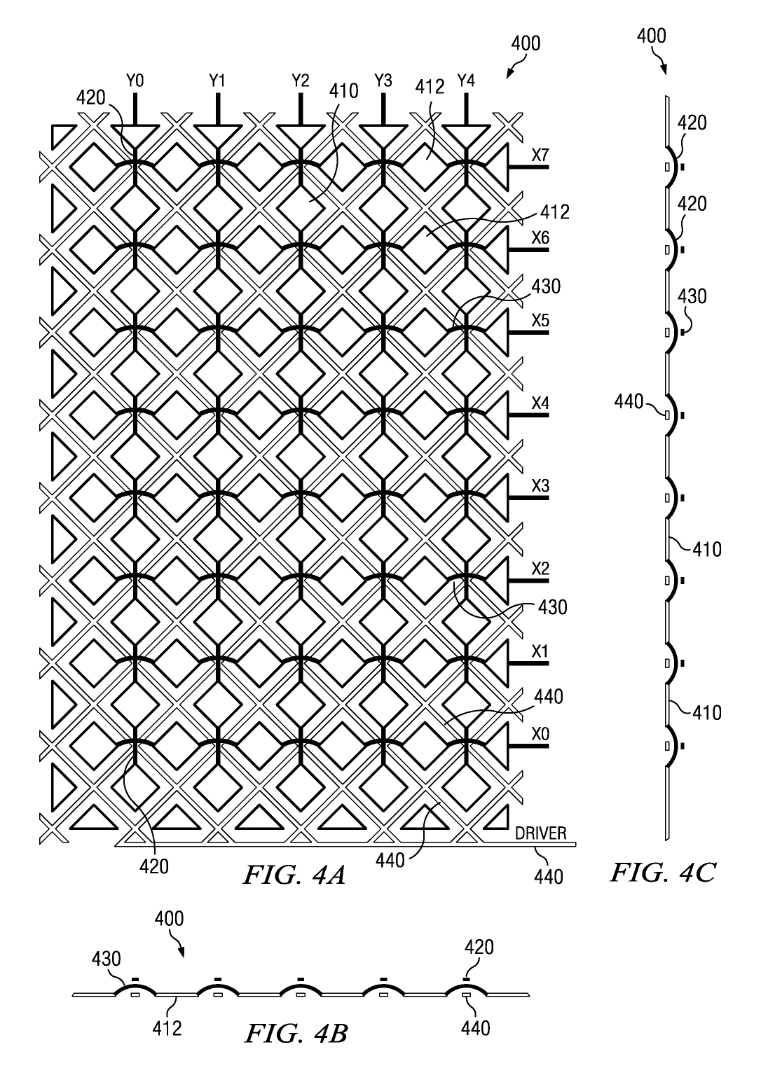

FIGS. 4A-4C illustrate an example single-layer sensor design with dual-layer bridges for an example touch screen 400. Screen 400 includes sense electrodes 410 and 412 and drive lines 440 arranged such that a drive line 440 is adjacent to every sense electrode 410 and 412. Bridges 420 may electrically couple sense electrodes 410 along a first axis and bridges 430 may electrically couple sense electrodes 412 along a second axis that is substantially perpendicular to the first axis. Drive lines 440 may carry a common drive signal for all of touch screen 400. One or more drive electrodes may form each drive line 440. Drive lines 440 and sense electrodes 410 and 412 may form capacitive nodes. For example, a drive line 440 and an adjacent sense electrode 410 or 412 may be capacitively coupled to each other across a gap between them and form a capacitive node. Drive lines 440 are not in electrical contact with sense electrodes 410 and 412—instead they are capacitively coupled to each other. A change in capacitance at a capacitive node in touch screen 400 may indicate a touch or the proximity of an object at the position of the capacitive node in touch screen 400.

In particular embodiments, sense electrodes 410 and 412 as well as drive lines 440 may be arranged in a first layer. The first layer may include glass, polycarbonate or PMMA (poly(methyl methacrylate)). Sense electrodes 410 and 412 as well as drive lines 440 may be made of PEDOT (poly(3,4-ethylenedioxythiophene)), ITO (indium tin oxide), or conductive mesh. Conductive mesh may include copper, silver or other conductive materials. In particular embodiments, sense electrodes 410 and 412 may have different suitable shapes. For example, sense electrodes 410 and 412 may be diamond-shaped (as FIG. 4A illustrates). As another example, sense electrodes 410 and 412 may have a snowflake shape. Other suitable shapes may be used.

As FIG. 4B illustrates, bridges 420 may be arranged in a second layer separate from the first layer. As FIG. 4C illustrates, bridges 430 may be arranged in a third layer separate from the first layer and the second layer. In particular embodiments, the second and third layers may include glass, polycarbonate or PMMA (poly(methyl methacrylate)) and bridges 420 and 430 may be made of PEDOT (poly(3,4-ethylenedioxythiophene)), ITO (indium tin oxide), or conductive mesh. Conductive mesh may include copper, silver or other conductive materials. An insulating layer may be used between the bridges 420 and 430 where they cross each other. Another insulating layer may be used between bridges 420 and drive lines 440 where they cross each other.

In particular embodiments, drive lines 440 may all be pulsed at substantially the same time and the pulse may be measured using sense electrodes 410 and 412 substantially simultaneously to determine whether and where a touch or proximity input has occurred on touch screen 400. In this manner, all sense electrodes 410 and 412 of touch screen 400 may be sensed at or near the same time. The coordinates of a touch on screen 400 or of an object's proximity to screen 400 may be determined based on which of sense electrodes 410 and 412 experienced a disturbance to the common pulse on driver lines 440. In particular embodiments, screen 400 may have better visibility properties as compared with screen 300 of FIG. 3 because it only has one layer that includes drive lines 440 and sense electrodes 410 (whereas screen 300 has two layers that include lines 310, 312, 320, and 322) while maintaining the benefits of using a common drive signal as discussed above with respect to FIG. 2.

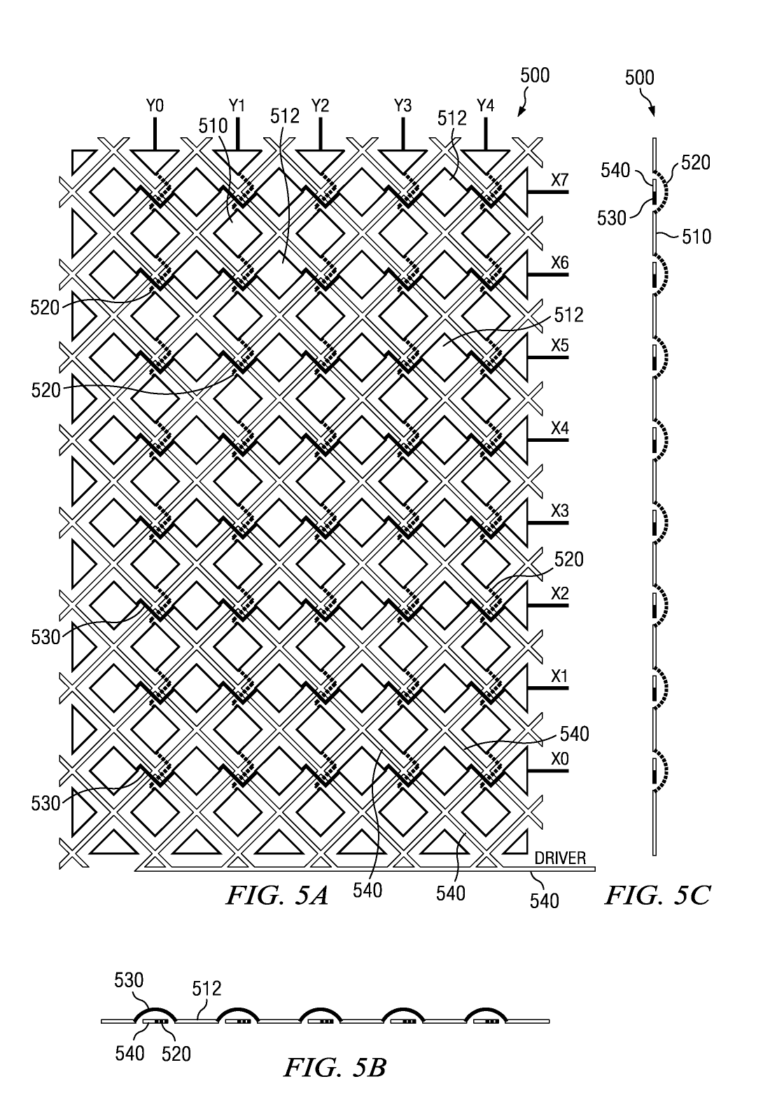

FIGS. 5A-5C illustrate an example single-layer sensor design with dual-layer bridges for an example touch screen 500. Screen 500 includes sense electrodes 510 and 512 and drive lines 540 arranged such that a drive line 540 is adjacent to every sense electrode 510 and 512. Bridges 520 may electrically couple sense electrodes 510 along a first axis and bridges 530 may electrically couple sense electrodes 512 along a second axis that is substantially perpendicular to the first axis. Drive lines 540 may carry a common drive signal for all of touch screen 400. One or more drive electrodes may form each drive line 540. Drive lines 540 and sense electrodes 510 and 512 may form capacitive nodes. For example, a drive line 540 and an adjacent sense electrode 510 or 512 may be capacitively coupled to each other across a gap between them and form a capacitive node. Drive lines 540 are not in electrical contact with sense electrodes 510 and 512—instead they are capacitively coupled to each other. A change in capacitance at a capacitive node in touch screen 500 may indicate a touch or the proximity of an object at the position of the capacitive node in touch screen 500.

In particular embodiments, sense electrodes 510 and 512 as well as drive lines 540 may be arranged in a first layer. The first layer may include glass, polycarbonate or PMMA (poly(methyl methacrylate)). Sense electrodes 510 and 512 as well as drive lines 540 may be made of PEDOT (poly(3,4-ethylenedioxythiophene)), ITO (indium tin oxide), or conductive mesh. Conductive mesh may include copper, silver or other conductive materials. In particular embodiments, sense electrodes 510 and 512 may have different suitable shapes. For example, sense electrodes 510 and 512 may be diamond-shaped (as FIG. 5A illustrates). As another example, sense electrodes 510 and 512 may have a snowflake shape. Other suitable shapes may be used.

As illustrated in FIGS. 5B and 5C, bridges 520 and 530 may be arranged in a second layer separate from the first layer. In particular embodiments, the second and third layers may include glass, polycarbonate or PMMA (poly(methyl methacrylate)) and bridges 420 and 430 may be made of PEDOT (poly(3,4-ethylenedioxythiophene)), ITO (indium tin oxide), or conductive mesh. Conductive mesh may include copper, silver or other conductive materials. An insulating layer may be used between bridges 520, bridges 530, and drive lines 540 where they cross each other.

In particular embodiments, drive lines 540 may all be pulsed at substantially the same time and the pulse may be measured using sense electrodes 510 and 512 substantially simultaneously to determine whether and where a touch or proximity input has occurred on touch screen 500. In this manner, all sense electrodes 510 and 512 of touch screen 500 may be sensed at or near the same time. The coordinates of a touch on screen 500 or of an object's proximity to screen 500 may be determined based on which of sense electrodes 510 and 512 experienced a disturbance to the common pulse on driver lines 540. In particular embodiments, screen 500 may have better visibility properties as compared with screen 300 of FIG. 3 because it only has one layer that includes drive lines 540 and sense electrodes 510 (whereas screen 300 has two layers that include lines 310, 312, 320, and 322) while maintaining the benefits of using a common drive signal as discussed above with respect to FIG. 2. Screen 500 may have better visibility properties as compared with screen 400 of FIG. 4 because it only has one layer that includes bridges 520 and 530 whereas screen 400 includes two layers that includes bridges 420 and 430. Screen 500 may also have better visibility properties as compared with screen 400 of FIG. 4 because it only uses one insulating layer at intersections of bridges 520, bridges 530, and drive lines 540 whereas screen 400 includes two insulating layers used at intersections of bridges 420 and 430 and intersections of bridges 420 and drive lines 440.

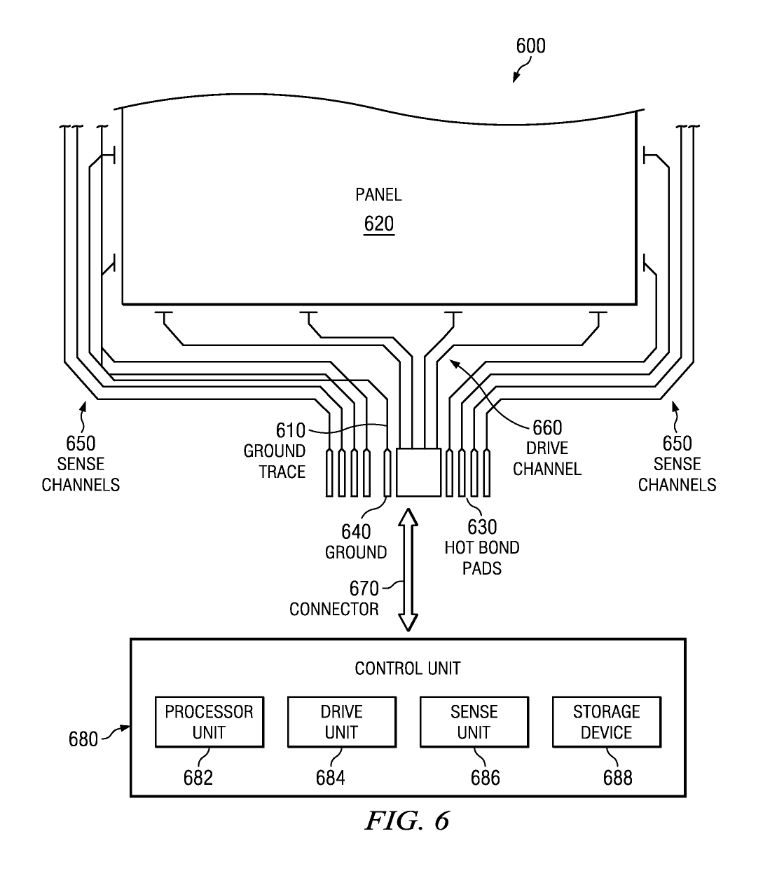

FIG. 6 illustrates an example touch-screen system 600. System 600 includes touch sensitive panel 620 that is coupled to hot bond pads 630 and ground 640 using ground trace 610, sense channels 650, drive channels 660. The drive and sense channels 650 and 660 are connected to a control unit 680 via a connector 670. In the example, the traces forming the channels have hot bond pads 630, to facilitate electrical connection via the connector 670. As an example, control unit 680 may cause a common drive signal to be sent to panel 620 via drive channel 660. Signals detected in panel 620 may be sent to control unit 680 via sense channels 650. As discussed further below, control unit 680 may process the signals to determine whether an object has contacted panel 620 or is in proximity to panel 620.

In particular embodiments, panel 620 may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with conductive material forming drive and sense electrodes. Panel 620 may also include a second layer of OCA and another substrate layer (which may be made of PET or another suitable material). The second layer of OCA may be disposed between the substrate with the conductive material making up the drive and sense electrodes and the other substrate layer, and the other substrate layer may be disposed between the second layer of OCA and an airgap to a display of a device including a touch sensor and a controller. As an example only and not by way of limitation, the cover panel may have a thickness of approximately 1 mm; the first layer of OCA may have a thickness of approximately 0.05 mm; the substrate with the conductive material forming the drive and sense electrodes may have a thickness of approximately 0.05 mm (including the conductive material forming the drive and sense electrodes); the second layer of OCA may have a thickness of approximately 0.05 mm; and the other layer of substrate disposed between the second layer of OCA and the airgap to the display may have a thickness of approximately 0.5 mm. Although this disclosure describes a particular number of particular layers made of particular materials and having particular thicknesses, this disclosure contemplates any suitable mechanical stack with any suitable number of any suitable layers made of any suitable materials and having any suitable thicknesses. In particular embodiments, panel 620 may be implemented using the embodiments disclosed above with respect to FIGS. 2-5C.

In particular embodiments, control unit 680 may be one or more integrated circuits (ICs)—such as for example general-purpose microprocessors, microcontrollers, programmable logic devices or arrays, application-specific ICs (ASICs), tangible, non-transitory, computer-readable storage media—on a flexible printed circuit (FPC). Control unit 680 may include processor unit 682, drive unit 684, sense unit 686, and storage device 688. Drive unit 684 may supply drive signals to the drive electrodes of panel 620. Control unit 680 may supply common drive signals to the drive electrodes of panel 620. Sense unit 686 may sense charge at the capacitive nodes included in panel 620 and provide measurement signals to processor unit 682 representing capacitances at the capacitive nodes. Processor unit 682 may control the supply of drive signals to the drive electrodes by drive unit 684 and process measurement signals from sense unit 686 to detect and process the presence and location of a touch or proximity input within the touch-sensitive area(s) of panel 620. Processor unit 682 may also track changes in the position of a touch or proximity input within the touch-sensitive area(s) of panel 620. Storage device 688 may store programming for execution by processor unit 682, including programming for controlling drive unit 684 to supply drive signals to the drive electrodes, programming for processing measurement signals from sense unit 686, and other suitable programming, where appropriate. Although this disclosure describes a particular control unit 680 having a particular implementation with particular components, this disclosure contemplates any suitable control unit having any suitable implementation with any suitable components.

Herein, reference to a computer-readable storage medium encompasses one or more non-transitory, tangible computer-readable storage media possessing structure. As an example and not by way of limitation, a computer-readable storage medium may include a semiconductor-based or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An apparatus comprising:
a touch sensor comprising:
a plurality of sense electrodes arranged along a first axis and a second axis, the first and second axes being substantially perpendicular to each other;
a plurality of drive electrodes; and
one or more computer-readable non-transitory storage media coupled to the touch sensor and embodying logic that is configured when executed to drive all the drive electrodes of the touch sensor substantially simultaneously with a common drive signal.

2. The apparatus of claim 1, wherein the touch sensor further comprises:
a first layer comprising:
a first set of the sense electrodes arranged along the first axis; and
a first set of the drive electrodes corresponding to the first set of the sense electrodes for capacitive coupling to them; and
a second layer comprising:
a second set of the sense electrodes arranged along the second axis; and
a second set of the plurality of drive electrodes corresponding to the second set of the sense electrodes.

3. The apparatus of claim 1, further comprising:
a first layer comprising the plurality of sense electrodes and the plurality of drive electrodes;
a second layer comprising a first set of bridges coupling a first portion of the plurality of sense electrodes along the first axis; and
a third layer comprising a second set of bridges coupling a second portion of the plurality of sense electrodes along the second axis.

4. The apparatus of claim 1, further comprising:
a first layer comprising the plurality of sense electrodes and the plurality of drive electrodes;
a second layer comprising:
a first set of bridges coupling a first portion of the plurality of sense electrodes along the first axis; and
a second set of bridges coupling a second portion of the plurality of sense electrodes along the second axis.

5. The apparatus of claim 1, wherein one or more of the plurality of sense electrodes is substantially diamond-shaped or substantially snowflake-shaped.

6. The apparatus of claim 1, wherein one or more portions of one or more of the drive or sense electrodes are made of: one or more conductive meshes of metal.

7. The apparatus of claim 1, wherein one or more portions of one or more of the drive or sense electrodes are made of indium tin oxide (ITO).

8. The apparatus of claim 1, wherein the logic is further configured to:
receive through the sense electrodes one or more sense signals resulting from the common drive signal;
analyze the sense signals for one or more disturbances relative to the common drive signal; and
in response to analyzing the sense signals, determine a location of a proximity input or touch input on the touch sensor.

9. A method comprising:
driving all drive electrodes of a touch sensor substantially simultaneously with a common drive signal, the touch sensor comprising:
a plurality of sense electrodes arranged along a first axis and a second axis, the first and second axes being substantially perpendicular to each other; and
a plurality of drive electrodes.

10. The method of claim 9, wherein the touch sensor further comprises:
a first layer comprising:
a first set of the sense electrodes arranged along the first axis; and
a first set of the drive electrodes corresponding to the first set of the sense electrodes for capacitive coupling to them; and
a second layer comprising:
a second set of the sense electrodes arranged along the second axis; and
a second set of the plurality of drive electrodes corresponding to the second set of the sense electrodes.

11. The method of claim 9, wherein the touch sensor further comprises:
a first layer comprising the plurality of sense electrodes and the plurality of drive electrodes;
a second layer comprising a first set of bridges coupling a first portion of the plurality of sense electrodes along the first axis; and
a third layer comprising a second set of bridges coupling a second portion of the plurality of sense electrodes along the second axis.

12. The method of claim 9, wherein the touch sensor further comprises:
a first layer comprising the plurality of sense electrodes and the plurality of drive electrodes;
a second layer comprising:
a first set of bridges coupling a first portion of the plurality of sense electrodes along the first axis; and
a second set of bridges coupling a second portion of the plurality of sense electrodes along the second axis.

13. The method of claim 9, wherein one or more of the plurality of sense electrodes is substantially diamond-shaped or substantially snowflake-shaped.

14. The method of claim 9, wherein one or more portions of one or more of the drive or sense electrodes are made of: one or more conductive meshes of metal.

15. The method of claim 9, wherein one or more portions of one or more of the drive or sense electrodes are made of indium tin oxide (ITO).

16. The method of claim 9, further comprising:
receiving through the sense electrodes one or more sense signals resulting from the common drive signal;
analyzing the sense signals for one or more disturbances relative to the common drive signal; and
in response to analyzing the sense signals, determining a location of a proximity input or touch input on the touch sensor.

17. One or more computer-readable non-transitory storage media embodying logic that is configured when executed to:
drive all drive electrodes of a touch sensor substantially simultaneously with a common drive signal, the touch sensor comprising:
a plurality of sense electrodes arranged along a first axis and a second axis, the first and second axes being substantially perpendicular to each other; and
a plurality of drive electrodes.

18. The media of claim 17, wherein the touch sensor further comprises:
a first layer comprising:
a first set of the sense electrodes arranged along the first axis; and
a first set of the drive electrodes corresponding to the first set of the sense electrodes for capacitive coupling to them; and
a second layer comprising:
a second set of the sense electrodes arranged along the second axis; and
a second set of the plurality of drive electrodes corresponding to the second set of the sense electrodes.

19. The media of claim 17, wherein the touch sensor further comprises:
a first layer comprising the plurality of sense electrodes and the plurality of drive electrodes;
a second layer comprising a first set of bridges coupling a first portion of the plurality of sense electrodes along the first axis; and
a third layer comprising a second set of bridges coupling a second portion of the plurality of sense electrodes along the second axis.

20. The media of claim 17, wherein the touch sensor further comprises:
a first layer comprising the plurality of sense electrodes and the plurality of drive electrodes;
a second layer comprising:
a first set of bridges coupling a first portion of the plurality of sense electrodes along the first axis; and
a second set of bridges coupling a second portion of the plurality of sense electrodes along the second axis.

21. The media of claim 17, wherein one or more of the plurality of sense electrodes is substantially diamond-shaped or substantially snowflake-shaped.

22. The media of claim 17, wherein one or more portions of one or more of the drive or sense electrodes are made of: one or more conductive meshes of metal.

23. The media of claim 17, wherein one or more portions of one or more of the drive or sense electrodes are made of indium tin oxide (ITO).

24. The media of claim 17, wherein the logic is further configured to:
receive through the sense electrodes one or more sense signals resulting from the common drive signal;
analyze the sense signals for one or more disturbances relative to the common drive signal; and
in response to analyzing the sense signals, determine a location of a proximity input or touch input on the touch sensor.
